(19) United States
(12) Patent Application Publication
(10) Pub. No.: US 2020/0087538 A1
(43) Pub. Date: Mar. 19, 2020

(54) COMPOSITION FOR SELECTIVE POLISHING OF WORK FUNCTION METALS

(71) Applicant: FUJIMI CORPORATION, Tualatin, OR (US)

(72) Inventor: Jie LIN, Tualatin, OR (US)

(73) Assignee: FUJIMI CORPORATION, Tualatin, OR (US)

(21) Appl. No.: 16/132,197

(22) Filed: Sep. 14, 2018

(51) Int. Cl. C09G 1/02; H01L 21/306

(52) U.S. Cl. CPC C09G 1/02; H01L 21/30625

(57) ABSTRACT

Provided herein are methods and compositions for selective polishing of a work function metal containing substrate. The present methods and compositions involve the use of a liquid carrier an anionic surfactant and a colloidal silica particle. The present methods and compositions can be used to achieve selective polishing of the work function metal.

### TECHNICAL FIELD

The present technology generally relates to planarization (CMP), e.g., CMP of high-k metal gate (HKMG) structures. The present technology relates to methods and slurries that achieve a selective polishing of work function metals in the presence of, e.g., metals such as Co and Al and dielectrics.

### BACKGROUND

CMP of HKMG structures is very important in the manufacturing of integrated circuit (IC). Replacement Metal Gate Extendible to 11 nm Technology, Naomi Yoshida et al. 2012 Symposium on VLSI Technology Digest of Technical Papers 81-82. There have been disclosures of slurry compositions for CMP of Co with corrosion inhibitors for protection of cobalt (Co) or tuning Co removal rate with selectivity to barrier films, such as Ta, TaN, Ti, and TiN, and dielectric films, such as TEOS (i.e. silicon dioxide, SiO₂, formed from tetraethyl orthosilicate), SiN, and low-k material. In manufacturing of HKMG structures, a slurry composition is needed for polishing work function metal such as TiN with selectivity to metals such as Co and Al and dielectrics such as TEOS and SiN.

A need exists in the art for a slurry composition that enables the polishing of a HKMG work function metal such as TiN in the presence of a conducting metal such as Co and Al, and is capable of stopping on dielectrics such as TEOS and SiN.

### SUMMARY OF THE DISCLOSURE

Provided herein are compositions and methods for CMP of metals, e.g., CMP of high-k metal gate structures. In one aspect, provided herein is a chemical mechanical polishing composition for selective polishing of a work function metal comprising: a liquid carrier; an anionic surfactant having a compound of the following formula (I): [alkyl-(OC₂H₅)ₙ—O]ₘ—PO_{q}Hᵣ, wherein n is 2-8, and (m, q, r) is (1, 3, 2), (2, 2, 1), or (3, 1, 0); a colloidal silica particle, wherein the composition has a pH range from about 6 to about 10. In some embodiments, the anionic surfactant comprises a mixture of a compound of formula (I) where m where (m, q, r) is (1, 3, 2) and (2, 2, 1). In some embodiments, the alkyl chain of the compound of formula (I) contains 6-24 carbon atoms. In some embodiments, the alkyl chain of the compound of formula (I) contains 12-14 carbon atoms. In some embodiments, n is 4-7. In some embodiments, the work function metal comprises TiN. In some embodiments, the chemical mechanical polishing composition further comprises a water-soluble polymer. In some embodiments, the chemical mechanical polishing composition further comprises a salt.

Other embodiments include a method of polishing a surface of a high-k metal gate (HKMG) structure comprising polishing the surface with a composition according to the previous embodiments. In some embodiments, the surface comprises a work function metal and at least one of Al and Co. In some embodiments, the work function metal comprises TiN. In some embodiments, the anionic surfactant has a concentration of about 0.1 to 1 mM.

Other embodiments include a method of suppressing the removal rate of Al and/or Co comprising polishing a surface comprising a work function metal and Al and/or Co with a composition according to the previous embodiments.

### DETAILED DESCRIPTION

Provided herein are compositions and related methods and systems for performing CMP of a surface. As used herein, the term “chemical mechanical polishing” or “planarization” refers to a process of planarizing (polishing) a surface with the combination of surface chemical reaction and mechanical abrasion. In some embodiments, the chemical reaction is initiated by applying to the surface a composition (interchangeably referred to as a ‘polishing slurry,’ a ‘polishing composition,’ a ‘slurry composition’ or simply a ‘slurry’) capable of reacting with a surface material, thereby turning the surface material into a product that can be more easily removed by simultaneous mechanical abrasion. In some embodiments, the mechanical abrasion is performed by contacting a polishing pad with the surface, and moving the polishing pad relative to the surface.

### Composition

The slurries for CMP disclosed herein can comprise, consist essentially of, or consist of the following components.

In some embodiments, the polishing slurry comprises a liquid carrier; an anionic surfactant and a colloidal silica particle. In some embodiments, the composition further comprises a water-soluble polymer and/or a salt.

The liquid carrier of the composition is not particularly limited. In some embodiments, the liquid carrier is water, such as deionized water. The liquid carrier may also be an aqueous solution that has, e.g., an appropriate pH modifier contained therein. In some embodiments, the liquid carrier can comprise one or more organic solvent, such as an alcohol compound, glycol ethers of aliphatic alcohols and 3 to 10 carbon atoms having 2 to 6 carbon atoms. Examples of aliphatic alcohols with 2 to 6 carbon atoms include ethanol, 1-propanol, 2-propanol, 1-butanol, 2-butanol, tert-butanol, pentanol, hexanol, ethylene glycol, propylene glycol, 1,3-butanediol, 1,4-butanediol, 1,5-pentanediol, 1,6-hexanediol, glycerin, 1,2,4-butanetriol, 1,2,6-hexanetriol, erythritol, D-threitol, L-threilol, D-arabinitol, L-arabinitol, ribitol, xylitol, mannitol, and sorbitol. Examples of glycol ethers with 3 to 10 carbon atoms include methyl glycol, methyl diglycol, methyl triglycol, isopropyl glycol, isopropyl diglycol, butyl glycol, butyl diglycol, butyl triglycol, isobutyl glycol, isobutyl diglycol, hexyl glycol, hexyl diglycol, 2-ethylhexyl glycol, 2-ethylhexyl diglycol, aryl glycol, phenyl glycol, phenyl diglycol, benzyl glycol, methylpropylene glycol, methylpropylene diglycol, methylpropylene triglycol, propylpropylene glycol, propylpropylene diglycol, butylpropylene glycol, butylpropylene diglycol, and phenylpropylene glycol.

The pH of the composition is generally a value of from about 6 to about 10. For example, the pH may be 6, 6.5, 7, 7.5, 8, 8.5, 9, 9.5, or 10. Appropriate pH adjusters and/or buffers may be included in the composition to adjust pH.

In some embodiments, an acid or an alkali is used as the pH-adjusting agent. The acid or alkali used in connection with the present invention can be organic or inorganic compounds. Examples of the acid include inorganic acids such as sulfuric acid, nitric acid, boric acid, carbonic acid, hypophosphorous acid, phosphorous acid, and phosphoric acid; and organic acids such as carboxylic acids including formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and organic sulfuric acids including methanesulfonic acid, ethanesulfonic acid, and isethionic acid. Examples of the alkali include hydroxides of an alkali metal, such as potassium hydroxide; ammonium hydroxide, ethylene diamine, and piperazine; and quaternary ammonium salts such as tetramethyl ammonium hydroxide and tetraethyl ammonium hydroxide. These acids or alkalis can be used either singly or in combination of two or more types.

Content of the acid or alkali in the slurry is not particularly limited as long as it is an amount allowing the slurry to be within the aforementioned pH range.

In some embodiments, the buffering material comprises one or more compounds selected from the group consisting of acetate salt, acetic acid, boric acid, ACES, AMP, AMPD, AMPSO, BES, bicine, Bis-Tris, Bis-Tris-Propane, borate salt, boric acid, cacodylate salt, CAPSO, CHES, citrate salt, citric acid, diethanolamine, 5,5-diethylbarbituric acid, DIPSO, EDTA, EPPS, ethanolamine, N-ethylmorpholine, formate salt, formic acid, glycine, glycylglycine, HERBS, HEPES, HEPPSO, L-histidine, hydrazine, imidazole, lactic acid, malate salt, maleate salt, maleic acid, malic acid, IVIES, methylamine, N-methyldiethanolamine, MOBS, MOPS, MOPSO, morpholine, PIPES, piperazine, phosphate salt, phosphoric acid, picolinic acid, POPSO, dihydrogen phosphate salt, potassium hydrogen phthalate, potassium hydrogen tartrate, potassium hydroxide, propionate, pyridine, hydrogen phosphate salt, sodium tetraborate decahydrate, TABS, TAPS, TAPSO, TEA, TES, tetraoxalate, tricine, trimethylamine, Tris, succinate salt, succinic acid, and taurine. In some embodiments, the buffering material is present in an amount of about 0.01 wt. % to about 4 wt. %.

The anionic surfactant of the composition contains a polyoxyethylene alky ether phosphate. The polyoxyethylene alky ether phosphate may comprise a monoester phosphate, diester phosphate, or mixture of the two. In some embodiments, the polyoxyethylene alky ether phosphate has the following structure: [(alkyl chain)-(polyethylene oxide) —O]ₘ-phosphoric acid, where m is 1 or 2 or 3. In some embodiments the polyoxyethylene alky ether phosphate has the following formula (I):

[alkyl-(OC₂H₅)ₙ—O]ₘ—PO_{q}Hᵣ,

wherein n is 2-8, and (m, q, r) is (1, 3, 2), (2, 2, 1), or (3, 1, 0). In some embodiments, n is independently in each instance selected from the group of 2, 3, 4, 5, 6, 7, and 8. In some embodiments, (m, q, r) is (1, 3, 2). In some embodiments, (m, q, r) is (2, 2, 1). In some embodiments, (m, q, r) is (3, 1, 0). In some embodiments, and (m, q, r) is a mixture of (1 3, 2), (2, 2, 1), and (3, 1, 0).

In some embodiments, the anionic surfactant is present in the composition at a concentration of about 0.1 to 1 For example, the anionic surfactant may be present in an amount of about 0.1, 0.2, 0.3, 0.4, 0.5, 0.6, 0.7, 0.8, and 0.9 or 1.0.

The composition also includes at least one abrasive. Examples of abrasives include, but are not limited to alumina, silica, or combinations thereof Silica includes precipitated silica, also typically called colloidal silica. The colloidal silica particle is not particularly limited. Commercially available colloidal silica particles may be used. In some embodiments, the average primary particle diameter of the abrasive grains is no more than 50 nm, is preferably no more than 35 nm, and is more preferably no more than 20 nm. In some embodiments, the average primary particle diameter of the abrasive grains is more than 5 mn. Particle diameter may be determined from a dynamic light scattering method. In some embodiments, the average secondary particle diameter of the abrasive grains is about 70 nm. In order to reduce scratch defects, the mean particle size of the abrasive is preferably controlled.

In some embodiments, the present slurry comprises about 0.01% to about 10% by weight of the abrasive. In some embodiments, the present slurry comprises less than 10% by weight of the abrasive. In some embodiments, the present slurry comprises less than 9% by weight of the abrasive. In some embodiments, the present slurry comprises less than 8% by weight of the abrasive. In some embodiments, the present slurry comprises less than 7% by weight of the abrasive. In some embodiments, the present slurry comprises less than 6% by weight of the abrasive. In some embodiments, the present slurry comprises less than 5% by weight of the abrasive. In some embodiments, the present slurry comprises less than 4% by weight of the abrasive. In some embodiments, the present slurry comprises less than 3% by weight of the abrasive. In some embodiments, the present slurry comprises less than 2% by weight of the abrasive. In some embodiments, the present slurry comprises less than 1% by weight of the abrasive. In some embodiments, the present slurry comprises less than 0.5% by weight of the abrasive. In some embodiments, the present slurry comprises less than 0.2% by weight of the abrasive.

The optional water-soluble polymer is also not particularly limited. Examples of the water soluble polymer include a polysaccharides such as alginic acid, pectic acid, agar, curdlan and pullulan; cellulose derivative such as hydroxymethyl cellulose, hydroxyethyl cellulose (HEC), hydroxypropyl cellulose, hydroxyethylmethyl cellulose, hydroxypropylmethyl cellulose, methyl cellulose, ethyl cellulose, ethylhydroxyethyl cellulose, or carboxymethyl cellulose; an imine derivative such as poly(N-acylalkyleneimine); polyvinyl alcohol; modified (cation modified or non-ion modified) polyvinyl alcohol; polyvinyl pyrrolidone; polyvinylcaprolactam; polyoxyalkylene such as polyoxyethylene; and a copolymer containing those constitutional units. The water-soluble polymer may be used either alone or as a mixture of two or more kinds. In some embodiments, the water-soluble polymer is capable of suppressing suppresses TEOS and/or SiN removal rate. For example, in some embodiments, the water-soluble polymer is polyvinyl pyrrolidone (PVP). In some embodiments, the water-soluble polymer has a molecular weight of from 5,000 to 300,000 g/mol (e.g., about 5,000, 10,000, 20,000, 30,000, 50,000, 75,000, 100,000, 150,000, 200,000, 250,000 or 300,000). In some embodiments, the weight-average molecular weight is a value from 5,000 to 300,000 g/mol (e.g., about 5,000, 10,000, 20,000, 30,000, 50,000, 75,000, 100,000, 150,000, 200,000, 250,000 or 300,000). In some embodiments, the concentration of the water-soluble polymer is about 0.05 wt. % to about 5 wt. % (e.g., 0.05, 0.1, 0.2, 0.3, 0.4, 0.5, 1, 1.5, 2, 2.5, 3, 3.5, 4, 4.5, or 5 wt. %).

The salt may be any salt that is suitable for polishing compositions. In some embodiments, the salt is suitable for adjusting ionic strength of the composition. For example, in some embodiments, the salt is a citrate salt, such as potassium citrate, e.g., tripotassium citrate. In some embodiments, the salt is a nitrate salt, such as sodium nitrate, potassium nitrate, ammonium nitrate. In some embodiments, the salt is a. acetate salt, such as sodium acetate, potassium acetate, ammonium acetate. The salt may also be in the hydrate form prior to addition.

In some embodiments, the composition according to the present disclosure may also comprise a biocide or other preservative. Examples of preservatives and biocides that may be used in connection with the present invention include an isothiazoline-based preservative such as 2-methyl-4-isothiazolin-3-one or 5-chloro-2-methyl-4-isothiazolin-3-one, paraoxybenzoate esters, and phenoxyethanol, and the like. These preservatives and biocides may be used either alone or in mixture of two or more kinds thereof.

### Methods

In another aspect of the present disclosure, provided herein are methods for CMP of an object having at least one metal surface. The method comprises contacting the metal surface with a polishing pad; delivering a polishing slurry according to the present disclosure to the metal surface; and polishing said metal surface with the polishing slurry. In some embodiments, the surface is of a high-k metal aate (HKMG) structure. In some embodiments, the object comprises a work function metal, such as Ta, TaN, Ti, and/or TiN. In some embodiments, the object comprises Co, Al, SiN, and/or TEOS. In some embodiments, the anionic surfactant is present in a concentration of about 0.1 to 1 mM.

In another aspect of the present disclosure, provided herein are methods for suppressing the removal rate of Al and/or Co during a CMP process. The method comprises using for the CMP a slurry according to the present disclosure. In some embodiments, the method comprises contacting the metal surface with a polishing pad; delivering a polishing slurry according to the present disclosure to the metal surface; and polishing said metal surface with the polishing slurry. In some embodiments, the surface is of a high-k metal gate (HKMG) structure. In some embodiments, the object comprises a work function metal, such as Ta, TaN, Ti, and/or TiN. In some embodiments, the object comprises Co, Al, SiN, and/or TEOS. In some embodiments, the anionic surfactant is present in a concentration of about 0.1 to 1 mM.

In another aspect of the present disclosure, provided herein are systems for chemical mechanical polishing (CMP). The system comprises a substrate comprising at least one metal surface, a polishing pad, and a polishing slurry according to the present disclosure.

In yet another aspect of the present disclosure, provided herein is a substrate comprising at least one metal surface, wherein the substrate is in contact with a CMP slurry according to the present disclosure.

In some embodiments, the suppression of the removal rate of Al and/or Co during a CMP process includes where the cobalt removal rate is about or less than 30 Å/minute. In some embodiments, the suppression of the removal rate of Al and/or Co during a CMP process includes where the cobalt removal rate is about or less than 25 Å/minute.

### EXAMPLES

### Example 1

A polishing composition was made comprising the following components: water, tripotassium citrate (3.2 g/L), PVP (Mw:10,000), ammonium lauryl sulfate (inhibitor), and colloidal silica (50 g/L). KOH was added to adjust the pH to 7.5, and H70₂ was included in 1 wt. %. The polishing compositions were used to polish a substrate having cobalt and aluminum. The removal rates of the Co and Al were measured at three different concentrations of the anionic surfactant inhibitor. The following tables show that inhibitor with phosphate functional group effectively suppresses Al and Co removal rate.

### Example 2

Three polishing compositions were made comprising the following components: water, tripotassium citrate (3.2 g/L), PVP (Mw:10,000), mixed lauryl and phosphate inhibitor, and colloidal silica (50 g/L). KOH was added to adjust the pH to 7.5, and H₂O₂ was included in 1 wt. %. The polishing compositions were used to polish a substrate having cobalt and aluminum. The removal rates of the Co and Al were measured at three different concentrations of the anionic surfactant inhibitor. The results in the following tables show that the inhibitors with polyethylene oxide suppress Al and Co removal rates.

Effect of Removal Rate by C₁₂/C₁₄-Phosphate Inhibitor

| | |
|---|---|
| I66 | RR (A/min) |

| (mM) | Al | Co |
|---|---|---|
| 0.00 | 1.0 | 1.0 |
| 0.27 | 0.30 | 0.99 |
| 0.80 | 0.28 | 0.04 |

*Solubility of inhibitor not high enough.

Effect of Removal Rate by C₁₂/C₁₄-(CH₂CH₂O)₄-Phosphate Inhibitor

| | |
|---|---|
| | Normalized |
| Inhibitor | removal rate |

| (mM) | Al | Co |
|---|---|---|
| 0.00 | 1.0 | 1.0 |
| 0.27 | 0.11 | 0.02 |
| 0.80 | 0.11 | 0.02 |

Effect of Removal Rate by C₁₂/C₁₄-(CH₂CH₂O)₉-Phosphate Inhibitor

| | |
|---|---|
| | Normalized |
| Inhibitor | removal rate |

| (mM) | Al | Co |
|---|---|---|
| 0.00 | 1.0 | 1.0 |
| 0.27 | 0.17 | 1.0 |
| 0.80 | 0.15 | 0.05 |

*With 0.8 mM of inhibitor, slurry becomes very viscous.

### Example 3

Four polishing compositions were made comprising the following components: water, tripotassium citrate (3.2 g/L), PVP (Mw:10,000), C₁₂/C₁₄-(CH₂CH₂O)₄-phosphate, and colloidal silica (50 g/L). KOH was added to adjust the pH to 7.5, and H₂O₂ was included in 1 wt. %. The results show that a composition having a polyoxyethylene alky ether phosphate and a water-soluble polymer such as PVP (Mw:10,000) enables the polishing of TiN, buffing of Al and Co, and stop on SiN and TEOS.

| | Slurry | | | |
|---|---|---|---|---|
| | Slurry 00 | Slurry 01 | Slurry 10 | Slurry 11 |
| C₁₂/C₁₄—(CH₂CH₂O)₄- | 0 | 0 | 0 | 1 |
| phosphate (g/L) | | | | |
| PVP (g/L) | 0 | 10 | 0.35 | 0.35 |
| Al (Å/min) | 244 | 902 | 12 | 20 |
| Co (Å/min) | 1061 | 1002 | 22 | 19 |
| TiN(Å/min) | 424 | 363 | 387 | 362 |
| SiN (Å/min) | 108 | 1.9 | 104 | 1.2 |
| TEOS (Å/min) | 130 | 2.1 | 128 | 1.8 |

### Comparative Example 1

Two polishing compositions were made. The sulfate composition was made comprising the following components: water, tripotassium citrate (3.2 g/L), PVP (Mw:10,000), ammonium lauiyl sulfate (inhibitor), and colloidal silica (50 g/L). KOH was added to adjust the pH to 7.5, and H₂O₂ was included in 1 wt. %. The carbonate composition was made comprising the following components: water, tripotassium citrate (3.2 g/L), PVP (Mw:10,000), potassium laurate (inhibitor), and colloidal silica (50 g/L). KOH was added to adjust the pH to 7.5, and H₂O₂ was included in 1 wt. %. The polishing compositions were used to polish a substrate having cobalt and aluminum. The removal rates of the Co and Al were measured at three different concentrations of the anionic surfactant inhibitor. The results in the following tables show that the inhibitors with sulfate and carbonate do not suppress Al and Co removal rate. Without being bound by theory, Applicant believes this is because sulfate and carbonate groups do not interact with Al and Co surface strongly to enable strong adsorption of inhibitors on the surface of Al and Co.

### Effect of Removal Rate by C₁₂-Sulfate Inhibitor

| | |
|---|---|
| | Normalized |
| Inhibitor | removal rate |

| (mM) | Al | Co |
|---|---|---|
| 0.00 | 1.0 | 1.0 |
| 0.27 | 1.0 | 1.1 |
| 0.80 | 1.2 | 1.1 |

*Normalized removal rate is used to eliminate effect of pad and polishing conditions.

### Effect of Removal Rate by C₁₂-Carbonate Inhibitor

| | |
|---|---|
| | Normalized |
| Inhibitor | removal rate |

| (mM) | Al | Co |
|---|---|---|
| 0.00 | 1.0 | 1.0 |
| 0.27 | 1.1 | 1.0 |
| 0.80 | 1.2 | 1.1 |

### Equivalents

The present technology is not to be limited in terms of the particular embodiments described in this application, which are intended as single illustrations of individual aspects of the present technology. Many modifications and variations of this present technology can be made without departing from its spirit and scope, as will be apparent to those skilled in the art. Functionally equivalent methods and apparatuses within the scope of the present technology, in addition to those enumerated herein, will be apparent to those skilled in the art from the foregoing descriptions. Such modifications and variations are intended to fall within the scope of the present technology. It is to be understood that this present technology is not limited to particular methods, reaaents, compounds compositions, or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed, range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

All numerical designations, e.g., pH, temperature, time, concentration, amounts, and molecular weight, including ranges, are approximations which are varied (+) or (−) by 10%, 1%, or 0.1%, as appropriate. It is to be understood, although not always explicitly stated, that all numerical designations may be preceded by the term “about.” As used herein, the term “about” will be understood by persons of ordinary skill in the art and will vary to some extent depending upon the context in which it is used. If there are uses of the term which are not clear to persons of ordinary skill in the art given the context in which it is used, “about” will mean up to plus or minus 10% of the particular term. It is also to be understood, although not always explicitly stated, that the reagents described herein are merely exemplary and that equivalents of such are known in the art.

All patents, patent applications, provisional applications, and publications referred to or cited herein are incorporated by reference in their entirety, including all figures and tables, to the extent they are not inconsistent with the explicit teachings of this specification.

Other embodiments are set forth in the following claims.

1. A chemical mechanical polishing composition for selective polishing of a work function metal comprising:
(a) a liquid carrier;
(b) an anionic surfactant having a compound of the following formula (I):
[alkyl-(OC₂H₅)ₙ—O]ₘ—PO_{q}Hᵣ, (I)
wherein n is 2-8, and (m, q, r) is (1, 3, 2), (2, 2, 1), or (3, 1, 0);
(e) a colloidal silica particle,
wherein the composition has a pH range from about 6 to about 10.

2. The composition of claim 1, wherein the anionic surfactant comprises a mixture of a compound of formula (I) where (m, q, r) is (1, 3, 2) and (2, 2, 1).

3. The composition of claim 1, wherein alkyl chain of the compound of formula (I) contains 6-24 carbon atoms.

4. The composition of claim 1, wherein alkyl chain of the compound of formula (I) contains 12-14 carbon atoms.

5. The composition of claim 1, wherein n is 4-7.

6. The composition of claim 1, wherein the work function metal comprises TiN.

7. The composition of claim 1, wherein the chemical mechanical polishing composition further comprises a water-soluble polymer.

8. The composition of claim 1, wherein the chemical mechanical polishing composition further comprises a salt.

9-13. (canceled)
